(19) United States
(12) Patent Application Publication
(10) Pub. No.: US 2022/0173264 A1
(43) Pub. Date: Jun. 2, 2022

(54) METHOD FOR PRODUCING BACK CONTACT SOLAR CELL

(71) Applicant: TOYO ALUMINIUM KABUSHIKI KAISHA, Osaka-shi, Osaka (JP)

(72) Inventors: Shota Suzuki, Osaka-shi (JP); Marwan Dhamrin, Osaka-shi (JP); Noboru Yamaguchi, Chigasaki-shi (JP); Hideo Suzuki, Chigasaki-shi (JP)

(73) Assignee: TOYO ALUMINIUM KABUSHIKI KAISHA, Osaka-shi, Osaka (JP)

(21) Appl. No.: 17/437,977

(22) PCT Filed: Mar. 13, 2020
(86) PCT No.: PCT/JP2020/011064

§ 371 Date: Sep. 10, 2021

(30) Foreign Application Priority Data
Mar. 13, 2019 (JP) 2019-045737

(51) Int. Cl. H01L 31/18; H01L 31/05; H01L 31/0224

(52) U.S. Cl. CPC H01L 31/1804; H01L 31/022441; H01L 31/0516

(57) ABSTRACT

A method for producing a back-contact solar cell, includes forming an oxide film on a back surface of a crystalline silicon substrate; forming a silicon thin film layer on an exposed surface of the oxide film; partially forming an n⁺ layer in the silicon thin film layer by ion implantation using a mechanical hard mask and activation annealing; forming a passivation film on each of both surfaces of the crystalline silicon substrate having the oxide film, the silicon thin film layer, and the n⁺ layer; and removing part of one or more regions of the passivation film formed on the back-surface side of the crystalline silicon substrate, the one or more regions not covering the n⁺ layer, and forming one or more aluminum electrodes on the exposed silicon thin film layer, in the stated order.

### TECHNICAL FIELD

The present invention relates to a method for producing a back-contact solar cell.

### BACKGROUND ART

In recent years, cells called back-contact solar cells (interdigitated back-contact (IBC) solar cells) with a structure in which n⁺ and p⁺ diffusion layers are provided on the back surface of a crystalline silicon substrate, and back-side electrodes are formed on the back surface, have been actively developed as crystalline solar cells with high conversion efficiency. In order to improve the characteristics of solar cells, a structure in which both surfaces of the crystalline silicon substrate of a solar cell are covered with an oxide film or nitride film to reduce the loss of power generated has been studied.

In a common silicon solar cell structure, electrodes are provided on the light-receiving (main surface) side and back-surface side of a solar cell. Thus, when electrodes are formed on the light-receiving (main surface) side, the amount of incident sunlight is reduced by the area of the electrodes, because the electrodes reflect and absorb sunlight. On the other hand, back-contact solar cells not only enable a decrease in wiring resistance by gathering wiring on the back-surface side, which reduces power loss, but also makes it possible to widen the light-receiving surface and take in more light because there is no need to provide electrodes on the light-receiving surface. As mentioned above, by forming a passivation film (e.g., an oxide film) for reducing power loss on the back surface of the crystalline silicon substrate of a solar cell, and forming a polycrystalline semiconductor layer on the passivation film, the passivation effect and the effect as an electrode are both achieved, improving power generation efficiency.

For example, Patent Literature (PTL) 1 discloses a back-contact solar cell in which an uneven shape is formed on the light-receiving surface of a crystalline silicon substrate by texture-etching and by using a peeling resin; a dielectric layer is formed to be in contact with the entire surface of the crystalline silicon substrate; an insulating layer is further formed; and patterning and etching are repeated to form n⁺ and p⁺ layers on the back side of the crystalline silicon substrate, thereby reducing short-circuiting between p- and n-electrodes.

However, the technique of PTL 1 requires repeated patterning and etching to form n⁺ and p⁺ layers, which increases the number of production steps. Additionally, there is a high risk of adhesive remaining due to printing, curing, and peeling of the peeling resin, and it takes time to clean the residue. Further, a vapor deposition method or a sputtering method is used to form n⁺ layer and p⁺ layer electrodes; however, these methods also require a long treatment time.

Furthermore, in order to improve the efficiency of conversion of sunlight into power, a solar cell structure called a passivating contact type has been developed in which both surfaces of a semiconductor substrate are covered with a passivation film, and power is extracted through the passivation film, achieving high power generation efficiency. However, a more complicated process than for conventional back-contact solar cells is required to achieve a structure that can extract power with both entire surfaces passivated (e.g., Non-patent Literature 1).

### CITATION LIST

### Patent Literature

PTL 1: JP2016-171095A

### Non-Patent Literature

NPL 1: “Laser contact openings for local poly-Si-metal contacts enabling 26.1% efficient POLO-IBC solar cells,” Felix Hasse, Solar Energy Materials and Solar Cells 186 (2018) 184-193

### SUMMARY OF INVENTION

### Technical Problem

In view of the circumstances described above, an object of the present invention is to provide a method for producing a back-contact solar cell that can be performed with fewer steps than conventional production methods.

### Solution to Problem

The present inventors conducted extensive research to achieve the object. They found that according to a production method comprising a specific step that uses ion implantation using a mechanical hard mask, back-contact solar cells can be produced with fewer steps than in conventional production methods. The inventors conducted further research on the basis of this finding, and completed the present invention.

Specifically, the present invention relates to the following method for producing a back-contact solar cell.

1. A method for producing a back-contact solar cell, comprising:

step (A) of forming an oxide film on a back surface of a crystalline silicon substrate;

step (B) of forming a silicon thin film layer on an exposed. surface of the oxide film;

step (C) of partially forming an n⁺ layer in the silicon thin film layer by ion implantation using a mechanical hard mask and activation annealing;

step (D) of forming a passivation film on each of both surfaces of the crystalline silicon substrate having the oxide film, the silicon thin film layer, and the n⁺ layer obtained in step (C); and

step (E) of removing part of one or more regions of the passivation film famed on the back-surface side of the crystalline silicon substrate, the one or more regions not covering the n⁺ layer, and forming one or more aluminum electrodes on the exposed silicon thin film layer, in this order.

2. The production method according to Item 1, wherein the method comprises, after step (D), step (E′) of removing part of one or more regions of the passivation film formed on the back-surface side of the crystalline silicon substrate, the one or more regions covering the crystalline silicon substrate via the oxide film and the n⁺ layer, and forming one or more silver electrodes on the exposed n⁺ layer; and step (E) and step (E′) are performed in any order.
3. The production method according to Item 2, wherein in step (E′), one or more copper electrodes or aluminum alloy electrodes are formed in place of the one or more silver electrodes.
4. The production method according to any one of Items 1 to 3, wherein the one or more aluminum electrodes are formed by firing a coating film of an aluminum paste containing 2 to 20 parts by mass of an organic vehicle and 0.15 to 15 parts by mass of a glass frit per 100 parts by mass of an aluminum powder at 650 to 900° C.
5. The production method according to Item 2, wherein the one or more aluminum electrodes and the one or more silver electrodes are formed so as to be alternately arranged on the back-surface side of the crystalline silicon substrate.

### Advantageous Effects of Invention

The method for producing a back-contact solar cell of the present invention eliminates the need for repeating patterning and etching to form n⁺ and p⁺ layers, and enables back-contact solar cells to be produced with fewer steps than conventional production methods. Accordingly, the production method of the present invention has a great advantage in terms of the production cost of back-contact solar cells. Further, since an n⁺ layer is famed by ion implantation using a mechanical hard mask and activation annealing, an insulating layer is provided between the n⁺ and p⁺ layers, suppressing leakage current (power loss) compared with conventional production methods.

### BRIEF DESCRIPTION OF DRAWINGS

FIG. 1-1 is an explanatory diagram of the method for producing a back-contact solar cell of the present invention (first part).

FIG. 1-2 is an explanatory diagram of the method for producing a back-contact solar cell of the present invention (latter part).

FIG. 2 is a schematic view of the back-contact solar cell of the Example.

FIG. 3 is an enlarged view of the schematic view of the back-contact solar cell of the Example.

FIG. 4 is an explanatory diagram of the layer structure in the back-contact solar cell of the Comparative Example.

FIG. 5 is a schematic view showing an example of an ion implanter applied to the method for producing a back-contact solar cell of the present invention.

### DESCRIPTION OF EMBODIMENTS

The method for producing a back-contact solar cell of the present invention comprises

step (A) of forming an oxide film on the back surface of a crystalline silicon substrate;

step (B) of forming a silicon thin film layer on the exposed surface of the oxide film;

step (C) of partially forming an n⁺ layer in the silicon thin film layer by ion implantation using a mechanical hard mask and activation annealing;

step (D) of forming a passivation film on each of both surfaces of the crystalline silicon substrate having the oxide film, the silicon thin film layer, and the n⁺ layer obtained in step (C); and

step (E) of removing part of one or more regions of the passivation film foamed on the back-surface side of the crystalline silicon substrate, the one or more regions not covering the n⁺ layer, and forming one or more aluminum electrodes on the exposed silicon thin film layer, in this order.

The method for producing a back-contact solar cell of the present invention, which has the above features, eliminates the need for repeating patterning and etching to form n⁺ and p⁺ layers, and enables back-contact solar cells to be produced with fewer steps than conventional production methods. Accordingly, the production method of the present invention has a great advantage in terms of the production cost of back-contact solar cells. Further, in the production method of the present invention, since an n⁺ layer is formed by ion implantation using a mechanical hard mask and activation annealing, an insulating layer is provided between the n⁺ and p⁺ layers, suppressing leakage current (power loss) compared with conventional production methods.

Each step of the method for producing a back-contact solar cell of the present invention (the production method of the present invention) is described below, with reference to the drawings as examples.

### Step (A)

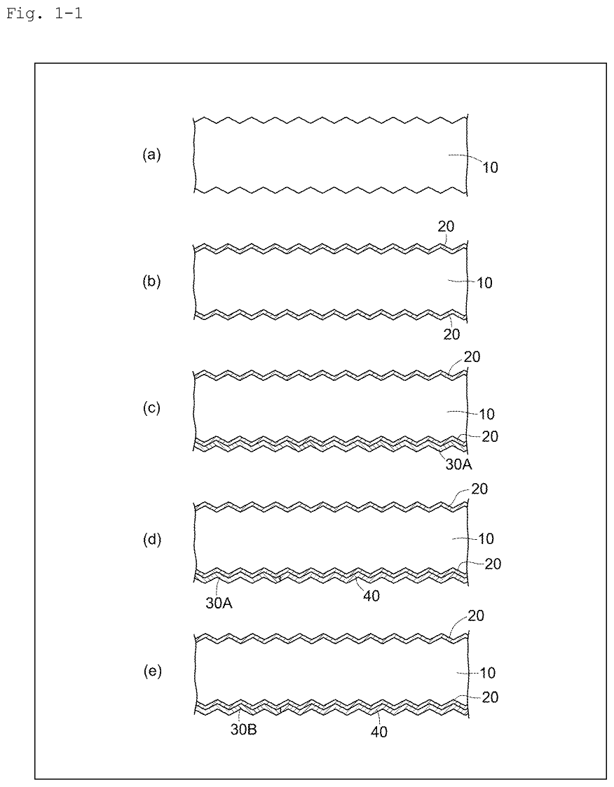

In step (A), on the back surface of a crystalline silicon substrate 10 (FIG. 1(a)), an oxide film 20 is formed (FIG. 1(b)).

The crystalline silicon substrate used is not particularly limited, and a wide range of known crystalline silicon substrates used in back-contact solar cells can be used. The crystalline silicon substrate may be either an n-type silicon semiconductor substrate or a p-type silicon semiconductor substrate, and can be appropriately selected according to the use and specifications of the desired solar cell. In the present specification, one surface of the crystalline silicon substrate is referred to as “the main surface” (light-receiving surface when used as a cell), and the other surface is referred to as “the back surface.”

Further, the crystalline silicon substrate may be wet-etched with an alkali liquid or the like beforehand in order to remove the damaged layer of the cut surface, and form a texture.

The thickness of the crystalline silicon substrate is not particularly limited, and may be, for example, 100 to 250 μm, and preferably 150 to 200 μm.

A known technique can be used for forming an oxide film on the back surface of the crystalline silicon substrate.

Specific examples include a technique of forming an oxide film by heating a crystalline silicon substrate; a technique of forming an oxide film by immersing a crystalline silicon substrate in nitric acid; a technique of forming an oxide film by immersing a crystalline silicon substrate in ozone water; and the like.

The thickness of the oxide film is not limited, and is preferably 0.5 to 4 nm, and more preferably 1.0 to 2.0 nm. In the production method of the present invention, it suffices if an oxide film is formed on the back surface (entire back surface) of the crystalline silicon substrate; however, if necessary, an oxide film may also be formed on the other surface (entire main surface) of the crystalline silicon substrate (FIG. 1(b) shows an embodiment in which an oxide film 20 is formed on each of the entire back and main surfaces (both surfaces) of the crystalline silicon substrate 10). In this case, the effect of suppressing leakage current while the solar cell is in use can be further enhanced.

### Step (B)

In step (B), a silicon thin film layer 30A is formed on the exposed surface of the oxide film (FIG. 1(c)). The oxide film means an oxide film formed on the back surface of the crystalline silicon substrate, which is always provided in step

A known technique can be used for forming a silicon thin film layer on the exposed surface of the oxide film formed on the back surface of the crystalline silicon substrate.

Specific examples include a plasma CVD method, an atmospheric-pressure CVD (APCVD) method for semiconductors, a low-pressure CVD (LPCVD) method for semiconductors, a sputtering method, and the like. The thickness of the silicon thin film layer is not limited, and is generally about 10 to 150 nm.

### Step (C)

In step (C), an n⁺ layer 40 is partially formed in the silicon thin film layer 30A by ion implantation using a mechanical hard mask and activation annealing (FIG. 1(d)). In FIG. 1(d), a portion 40 is a portion in which the n⁺ layer is formed, and a portion that remains 30A is a portion in which the n⁺ layer is not formed.

As ion implantation for forming the n⁺ layer, a known technique can be used. In the production method of the present invention, in particular, ion implantation using a mechanical hard mask is used. The mechanical hard mask is used for partially providing the n⁺ layer in the silicon thin film layer. The mechanical hard mask is, for example, a mechanical hard mask in which opening portions having a width of 700 μm and closed portions having a width of 300 μm are alternately arranged. In this case, the n⁺ layer 40 having a width of 700 μm is formed in such a pattern that the n⁺ layer 40 is formed at intervals of 300 μm (corresponding to the portion (30A) in which the n⁺ layer is not formed). The mechanical hard mask may be a known mechanical hard mask. Examples of the material of the mechanical hard mask include carbon-based materials, silicon-based materials, copper-based materials, quartz-based materials, and the like.

In ion implantation, for example, a technique can be used in which PH₃ (phosphine) as a raw material is ionized by generation of plasma, and then applied as an ion beam to a silicon thin film layer. In the application of the ion beam, a mechanical hard mask is used to separate a portion to be irradiated with the ion beam and a portion not to be irradiated with the ion beam. As an ion implanter for performing ion implantation, a known mass-separated ion implanter or non-mass-separated ion implanter can be used.

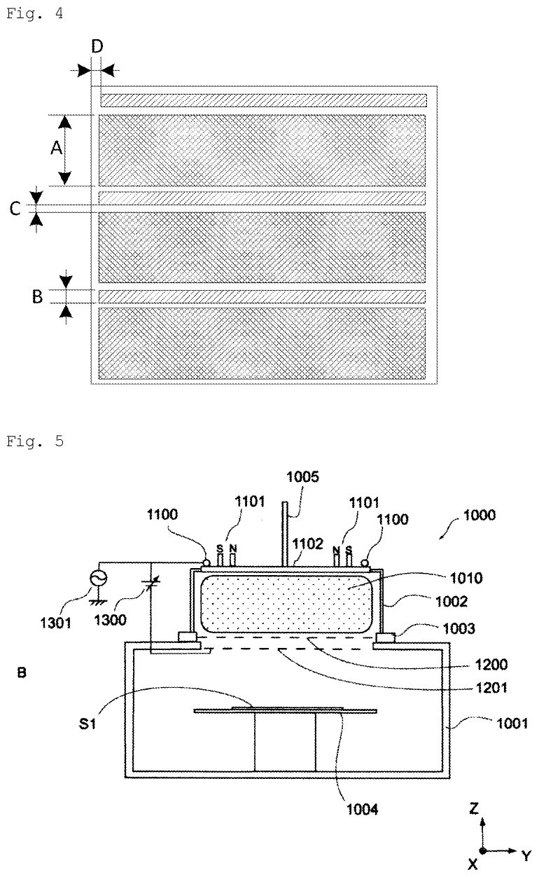

FIG. 5 is a schematic view of a non-mass-separated ion implanter. The outline is as follows.

The ion implanter 1000 shown in FIG. 5 includes a vacuum chamber 1001 (lower vacuum chamber) and a vacuum chamber 1002 (upper vacuum chamber), an insulating member 1003, a stage 1004, and a gas supply source 1005. The ion implanter 1000 further includes an RF introduction coil 1100, a permanent magnet 1101, an RF introduction window (quartz window) 1102, an electrode 1200, an electrode 1201, a DC power source 1300, and an AC power source 1301.

The vacuum chamber 1002 is smaller in diameter than the vacuum chamber 1001, and is provided on the vacuum chamber 1001 with the insulating member 1003 interposed therebetween. The vacuum chamber 1001 and the vacuum chamber 1002 can be maintained in a reduced-pressure state by using a vacuum evacuation means, such as a turbo-molecular pump. The stage 1004 is provided in the vacuum chamber 1001. The stage 1004 can support a substrate S1. A heating mechanism for heating the substrate S1 may be provided in the stage 1004. The substrate S1 is a crystalline silicon substrate (which has an oxide film and a silicon thin film layer on the back-surface side, and in which part of the silicon thin film layer is the target of ion implantation) used in the production method of the present invention. Gas for ion implantation is introduced into the vacuum chamber 1002 by the gas supply source 1005.

The RF introduction coil 1100 is placed on the RF introduction window 1102 so as to surround the permanent magnet 1101. The permanent magnet 1101 has a ring shape. The RF introduction coil 1100 has a coil shape. The diameter of the RF introduction coil 1100 can be appropriately set according to the size of the substrate S1. When gas for ion implantation is introduced into the vacuum chamber 1002, and predetermined power is supplied to the RF introduction coil 1100 from the AC power source 1301, plasma 1010 is generated in the vacuum chamber 1002 by inductively coupled plasma (ICP) discharge.

The electrode 1200 is an electrode having multiple openings (e.g., a mesh electrode), and is supported by the insulating member 1003. The potential of the electrode 1200 is a floating potential. Due to this, the stable plasma 1010 is generated in the space surrounded by the vacuum chamber 1002 and the electrode 1200.

Another electrode 1201 having multiple openings (e.g., a mesh electrode) is placed below the electrode 1200. The electrode 1201 faces the substrate S1. The DC power source 1300 is connected between the electrode 1201 and the RF introduction coil 1100, and a negative potential (acceleration voltage) is applied to the electrode 1201. Due to this, positive ions in the plasma 1010 are extracted from the plasma 1010 by the electrode 1201.

The extracted positive ions can pass through the mesh-shaped electrodes 1200, 1201 and reach the substrate S1. In the ion implanter 1000, the acceleration voltage of the positive ions can be set in the range of, for example, 1 kV or more and 30 kV or less. A bias power source capable of adjusting the acceleration voltage may be connected to the stage 1004.

Gas containing an impurity element (n-type impurity element) to be implanted into the substrate S1 is introduced into the vacuum chamber 1002. The plasma 1010 is formed in the vacuum chamber 1002 by this gas, and n-type impurity ions in the plasma 1010 are implanted into the substrate S1. The n-type impurity ions are, for example, at least one of P, PX⁺, PX²⁺, PX³⁺, and the like. Here, “X” is hydrogen or halogen (F, Cl).

In the present embodiment, the means for forming the plasma 1010 is not limited to the ICP method, and may be an electron cyclotron resonance plasma method, a helicon wave plasma method, or the like. When n-type impurity ions are implanted into the substrate S1, a gas containing hydrogen (e.g., PH₃ or BH₂) may be added to the gas for ion implantation, from the viewpoint of repairing lattice defects in the substrate S1.

The conditions for activation annealing are not limited, and the temperature is preferably 600 to 1000° C., and more preferably 700 to 900° C. Regarding the atmosphere during annealing, it is preferable that there is a step in which the oxygen concentration is set in the range of 1 to 100%, more preferably 5 to 50%. Through this activation annealing, the silicon thin film layer 30A (especially amorphous silicon thin film layer or microcrystalline silicon thin film layer) is changed into a polycrystalline silicon thin film layer 30B. Thus, the silicon thin film layer in the subsequent steps means the polycrystalline silicon thin film layer 30B.

The thickness of the n⁺ layer is not particularly limited, and is preferably 0.1 to 2 μm, and more preferably 0.3 to 1 μm.

### Step (D)

In step (D), a passivation film 50 is formed on each of both surfaces of the crystalline silicon substrate having the oxide film 20, the silicon thin film layer (polycrystalline silicon thin film layer; the same applies to the following) 30B, and the n⁺ layer 40, obtained in step (C) (FIG. 1(f)). Specifically, on the back-surface side of the crystalline silicon substrate, regarding a portion in which the n⁺ layer 40 is famed in step (C), the passivation film 50 is formed on the n⁺ layer 40; and regarding a portion in which the n⁺ layer is not present, the passivation film is formed on the silicon thin film layer 30B. On the main-surface side of the crystalline silicon substrate, the passivation film is formed on the crystalline silicon substrate directly, or with an optionally formed oxide film interposed therebetween.

The passivation film is not particularly limited as long as it has a passivation effect due to fixed charge in the solar cell of the present invention. Specifically, the passivation film may be, for example, one or more members selected from the group consisting of a silicon nitride film, a silicon oxide film, an aluminum oxide film, an amorphous silicon film, and a microcrystalline silicon film. These films may each be a single layer comprising only one layer, or a laminate comprising multiple various layers.

The method for forming the passivation film is not particularly limited. Examples include chemical vapor deposition methods, such as a plasma CVD method, an atmospheric-pressure CVD method for semiconductors, and an atomic layer deposition (ALD) method; and sputtering methods. Specific examples include a method in which a passivation film made of aluminum oxide is formed by an ALD method using trimethylaluminum as a starting material.

The thickness of the passivation film is not particularly limited, and is preferably 5 to 200 nm, and more preferably 10 to 80 nm, from the viewpoint of the passivation effect and the workability the below-described passivation film removal step. It is preferable that an anti-reflection film (not shown) is further provided on e surface of the passivation film. The anti-reflection film is obtained, for example, by forming a silicon nitride film on the surface of the passivation film under an atmosphere of silane gas and ammonia gas by a plasma CVD method.

### Step (E)

In step (E), part of one or more regions of the passivation film formed on the back-surface side of the crystalline silicon substrate, the one or more regions not covering the n⁺ layer, is removed (FIG. 1(g)), and one or more aluminum electrodes 60B are formed on the exposed silicon thin film layer 30B (FIG. 1(i)). When the passivation film is removed at multiple locations, it is preferable to provide one aluminum electrode for each exposed portion of the silicon thin film layer.

A portion of the passivation film to be removed is part of a region of the passivation film formed on the back-surface side of the crystalline silicon substrate, the region not covering the n⁺ layer. The method for removing the passivation film is not particularly limited. Examples include a method using an etching paste, and a laser beam irradiation method.

The method for forming one or more aluminum electrodes on the exposed silicon thin film layer after removal of the passivation film is not particularly limited, and a wide range of known methods can be used. Specific examples include a method in which an aluminum paste 60A is provided on the exposed silicon thin film layer by an appropriate method, such as coating, and fired (FIG. 1(h) shows the state before firing, and FIG. 1(i) shows the state after firing). By this method, an aluminum-silicon alloy layer 60C and a BSF layer 60D are formed on the silicon thin film layer 30B (FIG. 1(i)). In FIG. 1(i), the aluminum paste is fired to form an aluminum-silicon alloy layer and a BSF layer on the silicon thin film layer, thereby obtaining an aluminum electrode 60B.

The firing temperature of the aluminum paste is not particularly limited, and is preferably, for example, 650 to 900° C. The composition of the aluminum paste is not particularly limited, and the aluminum paste is preferably, for example, a paste comprising 2 to 20 parts by mass of an organic vehicle containing a resin and/or an organic solvent and 0.15 to 15 parts by mass of a glass frit per 100 parts by mass of an aluminum powder.

Further, the aluminum powder may be high-purity aluminum or may be an aluminum alloy, and an aluminum silicon alloy or an aluminum silicon magnesium alloy is suitably used.

Regarding the shape and size of the aluminum electrode(s), the aluminum electrode(s) preferably have a width of 40 μm to 200 μm due to the need to cover the exposed silicon thin film layer; and in order to lower the resistance value of the electrode(s), the higher the electrode height, the better.

The larger the aspect (width/height) ratio of the printed Al line, the better.

### Step (E′)

Step (E′) is a step of, after step (D), removing part of one or more regions of the passivation film formed on the back-surface side of the crystalline silicon substrate, the one or more regions covering the crystalline silicon substrate via the oxide film and the n⁺ layer, and forming one or more silver electrodes 70B on the exposed n⁺ layer 40. Steps (E) and (E′) may be performed in any order. When the passivation film is removed at multiple locations, it is preferable to provide one silver electrode for each exposed portion of the n⁺ layer. As mentioned above, after step (D) is performed, either step (E) or step (E′) may be performed first.

The method for removing the passivation film is not particularly limited. Examples include a method in which a paste obtained by adding a component for removing the passivation film to a silver paste 70A (a so-called fire-through silver paste) is applied, and fired in the range of 550 to 900° C. to form a silver electrode while removing the passivation film directly under the paste (the method shown in FIG. 1(h)-FIG. 1(i)); a method of applying an etching paste; a method of irradiation with a laser beam; and the like.

In the case of using the fire-through silver paste, for example, the silver paste 70A can be applied to the surface of the passivation film as shown in FIG. 1(h), and then fired in the range of 550 to 900° C. to thereby form a silver electrode 70B on the exposed n⁺ layer while removing the passivation film directly under the paste applied, as shown in FIG. 1(i).

The composition of the silver paste is not particularly limited, and the silver paste is preferably, for example, a paste comprising 0.1 to 10 parts by mass of a glass frit and 3 to 15 parts by mass of an organic vehicle containing a resin and/or an organic solvent per 100 parts by mass of a silver powder. The silver powder may be in the form of flakes or may have a spherical shape, and a spherical silver powder is preferably used. Although one or more silver electrodes are formed in this step, one or more copper electrodes or aluminum alloy electrodes (which are different from the aluminum electrode(s) formed in step (E); in the present specification, the terms “aluminum electrode” and “aluminum alloy electrode” are distinguished from each other) may be formed in place of the silver electrode(s). Thus, in the present invention, a wide range of techniques known in the technical field of solar cells can be applied.

Regarding the shape and size of the silver electrode(s), a 50 to 130 μm straight line is printed so that silver electrode(s) are disposed so as to be interdigitated with aluminum electrode(s).

Embodiments of the present invention are described above. However, the present invention is not limited to these embodiments, and various embodiments may be made without departing from the spirit and principal concept of the invention.

### EXAMPLES

The following describes embodiments of the present invention in more detail, with reference to Examples. However, the present invention is not limited to these embodiments.

### Example 1

A crystalline silicon substrate made of p-type monocrystalline silicon was prepared (FIG. 1(a)) (substrate: 6 inches, a thickness of 200 μm). The surface of the crystalline silicon substrate was wet-etched with potassium hydroxide in order to remove the damaged layer of the cut surface of the crystalline silicon substrate, and form a texture.

### Step (A)

The crystalline silicon substrate was immersed in a nitric acid solution to form a silicon oxide film on each of both surfaces (FIG. 1(b)).

### Step (B)

A silicon thin film layer (amorphous silicon thin film layer) was formed to have a thickness of 200 nm on the back surface of the crystalline silicon substrate (having the oxide films) by a CVD method (FIG. 1(c)).

### Step (C)

Subsequently, a P element was implanted into the silicon thin film layer by an ion implantation method in which PH₃ (phosphine) was used as a raw material and the ionized raw material after generation of plasma was applied to the surface of the silicon thin film layer (FIG. 1(d)), followed by activation annealing, thereby partially forming an n⁺ layer to have a thickness of about 0.1 to 1 μm (FIG. 1(e)). The activation annealing also has the effect of poly-crystallizing the amorphous silicon thin film layer.

By using a mechanical hard mask in which opening portions having a width of 700 μam and closed portions having a width of 300 μam are alternately arranged, for the surface of the silicon thin film layer, the P element was implanted so that a region in which the n⁺ layer was formed and a region in which no n⁺ layer was foamed were alternated.

### Step (D)

Subsequently, a passivation film made of aluminum oxide was formed to have a thickness of about 10 to 50 nm by a plasma CVD method; and then a silicon nitride film was formed as an anti-reflection film for the entire crystalline silicon substrate (on each of the main-surface side and the back-surface side), using silane gas and ammonia gas by a plasma CVD method (FIG. 1(f)) (in the drawings, the anti-reflection film is not shown).

### Step (E)

Subsequently, the step of forming an opening for p⁺ layer formation using an aluminum electrode was performed. Specifically, for the passivation film in a region that does not cover the n⁺ layer formed, laser irradiation was performed in a line shape with a depth of 0.1 to 1.0 μm and a width of 30 μm in the center of the region that does not cover the n⁺ layer formed, thereby providing an opening for p⁺ layer formation using an aluminum electrode (FIG. 1(g)).

Thereafter, an aluminum paste was applied in a line shape with a thickness of 20 μm and a width of 70 μm using a screen printer so as to fill the opening for p⁺ layer formation, and the crystalline silicon substrate to which the aluminum paste was applied was dried at 100° C. for 10 minutes (FIG. 1(h)).

### Step (E′)

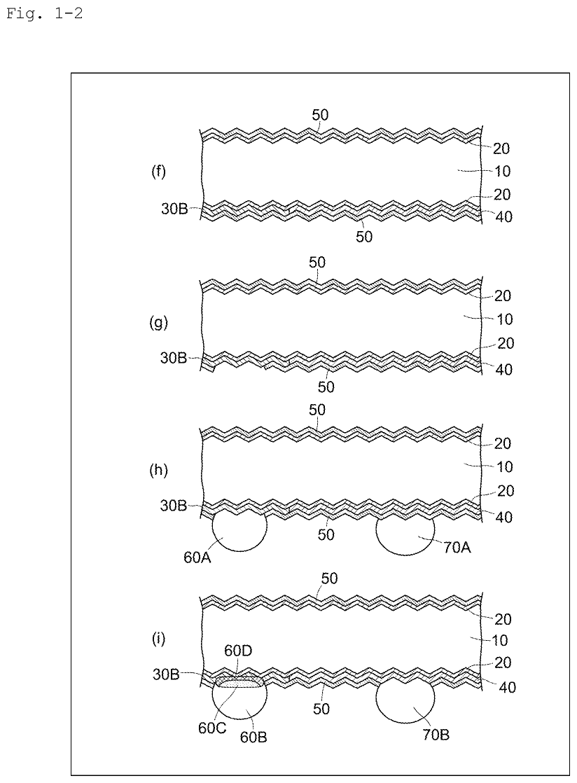

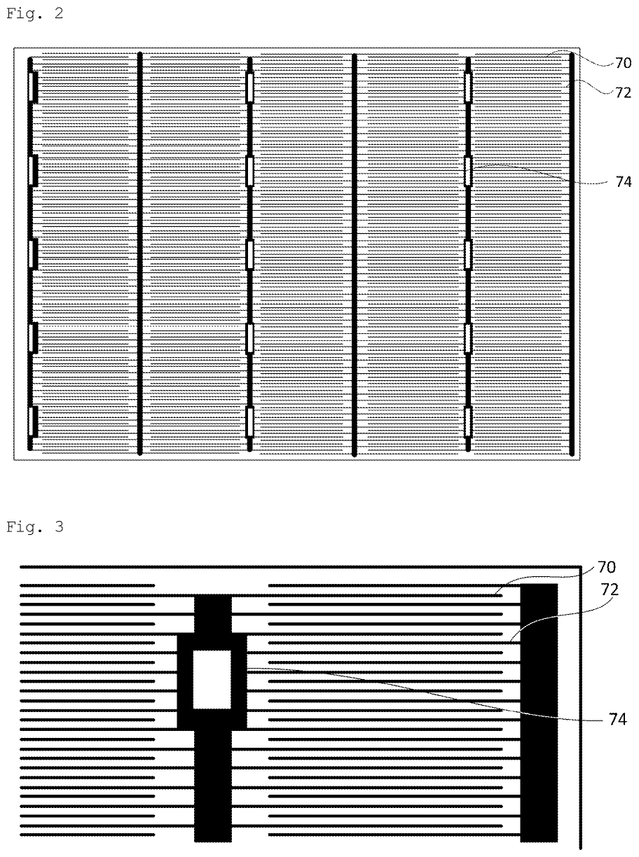

A known silver paste was printed at a printing width of 50 μm so that the distance from center to center in the width direction of silver electrodes was 1000 μm, in order to be interdigitated with aluminum electrodes as shown in FIGS. 2 and 3; and dried at 100° C. for 10 minutes (FIG. 1(h)). Firing was then performed in a belt furnace in which the peak temperature was set to 900° C. (FIG. 1(i)). Through this firing, aluminum electrodes (including the p⁺ layer) were formed, and silver electrodes were formed on the surface of the n⁺ layer.

In the manner described above, a back-contact solar cell was obtained.

Since the process of Example 1 was simple, the time required to produce the back-contact solar cell was 260 minutes.

For reference, in a comparison with an embodiment in which steps (A) and (B) were not performed in Example 1, the difference in time required to produce a back-contact solar cell was 30 minutes. In terms of production cost and leakage current suppression effect, the open-circuit voltage (Voc) characteristic was improved by 1.5% due to leakage current suppression; and the fill factor characteristic was improved by 2.5%, resulting in a reduction in production cost per unit of power generated.

### Comparative Example 1

As in conventional techniques, the light-receiving surface of a crystalline silicon substrate was texture-etched to form an uneven shape; a silicon oxide film was formed so as to be in contact with the entire surface of the crystalline silicon substrate; a silicon thin film layer (amorphous silicon thin film layer) was further formed; and impurities were repeatedly implanted by ion implantation to form n⁺ and p⁺ layers on the front and back surfaces of the crystalline silicon substrate, thereby obtaining a back-contact solar cell. The specific procedure is described in detail below.

First, a crystalline silicon substrate made of p-type monocrystalline silicon was prepared (substrate: 6 inches, a thickness of 200 μm). The front and back of the prepared crystalline silicon substrate was wet-etched with a solution, such as a mixture of hydrofluoric acid and nitric acid, in order to remove the damaged layer of the cut surface of the crystalline silicon substrate.

Subsequently, the crystalline silicon substrate was immersed in a nitric acid solution to form a silicon oxide film on each of both surfaces.

Thereafter, a silicon thin film layer (amorphous silicon thin film layer) was formed to have a thickness of 200 nm on each of both surfaces. As shown in FIG. 4, a pattern in which p-type and n-type diffusion layers were alternately formed in a stripe shape was formed in the silicon thin film layer on the back surface by ion implantation using a resist mask.

Specifically, the width of the n-type diffusion region (A) was 700 μm, the width of the p-type diffusion region (B) was 200 μm, the space between the n-type and p-type diffusion regions (C) was 50 μm, and the space between the diffusion layer edges closest to the substrate edge and the substrate edge (D) was 1000 μm. After that, by annealing at 875° C. in a heating furnace, the p⁺ and n⁺ layers were activated, and the amorphous silicon thin film layers were changed into polycrystalline silicon thin film layers.

Then, after a passivation film made of silicon oxide was formed to have a thickness of about 30 to 50 nm by a plasma CVD method, a passivation film made of aluminum oxide was further formed to have a thickness of 10 to 30 nm on the back surface by an ALD method. Thereafter, a silicon nitride film was formed as an anti-reflection film on the back-surface side of the crystalline silicon substrate by a plasma CVD method using silane gas and ammonia gas.

Subsequently, in order to form electrodes, patterning was performed on the back-surface side of the crystalline silicon substrate, and aluminum electrodes were formed by aluminum vapor deposition.

After that, Ni, Cu, and Ag plating was performed to make contact with aluminum, and annealing was performed. The formed electrodes were separated into electrodes that make contact with the p⁺ layer and electrodes that make contact with the n⁺ layer by using a laser irradiation device.

In the manner described above, a back-contact solar cell was obtained.

Since the process was complicated, the time required was 350 minutes.

### DESCRIPTION OF THE REFERENCE NUMERALS

10: Crystalline silicon substrate
20: Oxide film
30A: Silicon thin film layer
30B: Silicon thin film layer (after activation annealing)
40: n⁺ layer
50: Passivation film
60A: Aluminum paste for forming aluminum electrodes
60B: Aluminum electrode
60C: Aluminum-silicon alloy layer
60D: BSF layer
70A: Silver paste for forming silver electrodes
70B: Silver electrode
70: Aluminum electrode
72: Silver electrode
74: Silver electrode for aluminum joining
A: Width of n-type diffusion region
B: Width of p-type diffusion region
C: Space between n-type diffusion region and p-type diffusion region
D: Space between diffusion layer edges closest to substrate edge and substrate edge
1000: Ion implanter
1001, 1002: Vacuum chamber
1003: Insulating member
1004: Stage
1005: Gas supply source
1010: Plasma
1100: RF introduction coil
1101: Permanent magnet
1102: RF introduction window
1200, 1201: Electrode
1300: DC power source
1301: AC power source
S1: Substrate

1. A method for producing a back-contact solar cell, comprising:
step (A) of forming an oxide film on a back surface of a crystalline silicon substrate;
step (B) of forming a silicon thin film layer on an exposed surface of the oxide film;
step (C) of partially forming an n⁺ layer in the silicon thin film layer by ion implantation using a mechanical hard mask and activation annealing;
step (D) of forming a passivation film on each of both surfaces of the crystalline silicon substrate having the oxide film, the silicon thin film layer, and the n⁺ layer obtained in step (C); and
step (E) of removing part of one or more regions of the passivation film formed on the back-surface side of the crystalline silicon substrate, the one or more regions not covering the n⁺ layer, and forming one or more aluminum electrodes on the exposed silicon thin film layer, in this order.

2. The production method according to claim 1, wherein the method comprises, after step (D), step (E′) of removing part of one or more regions of the passivation film formed on the back-surface side of the crystalline silicon substrate, the one or more regions covering the crystalline silicon substrate via the oxide film and the n⁺ layer, and forming one or more silver electrodes on the exposed n⁺ layer; and
step (E) and step (E′) are performed in any order.

3. The production method according to claim 2, wherein in step (E′), one or more copper electrodes or aluminum alloy electrodes are formed in place of the one or more silver electrodes.

4. The production method according to claim 1, wherein the one or more aluminum electrodes are formed by firing a coating film of an aluminum paste containing 2 to 20 parts by mass of an organic vehicle and 0.15 to 15 parts by mass of a glass frit per 100 parts by mass of an aluminum powder at 650 to 900° C.

5. The production method according to claim 2, wherein the one or more aluminum electrodes and the one or more silver electrodes are formed so as to be alternately arranged on the back-surface side of the crystalline silicon substrate.

6. The production method according to claim 2, wherein the one or more aluminum electrodes are formed by firing a coating film of an aluminum paste containing 2 to 20 parts by mass of an organic vehicle and 0.15 to 15 parts by mass of a glass frit per 100 parts by mass of an aluminum powder at 650 to 900° C.

7. The production method according to claim 3, wherein the one or more aluminum electrodes are formed by firing a coating film of an aluminum paste containing 2 to 20 parts by mass of an organic vehicle and 0.15 to 15 parts by mass of a glass frit per 100 parts by mass of an aluminum powder at 650 to 900° C.
